(19) United States
(12) Patent Application Publication
(10) Pub. No.: US 2011/0195201 A1
(43) Pub. Date: Aug. 11, 2011

(54) METHOD FOR MAKING A NANO-OPTICAL ANTENNA ARRAY

(75) Inventors: ZHEN-DONG ZHU, Beijing (CN); QUN-QING LI, Beijing (CN); MO CHEN, Beijing (CN); LI-HUI ZHANG, Beijing (CN); SHOU-SHAN FAN, Beijing (CN)

(73) Assignees: TSINGHUA UNIVERSITY, Beijing (CN); HON HAI PRECISION INDUSTRY CO., LTD., Tu-Cheng (TW)

(21) Appl. No.: 12/872,144

(22) Filed: Aug. 31, 2010

(30) Foreign Application Priority Data
Feb. 6, 2010 (CN) 201010110157.1

(51) Int. Cl. B05D 3/06; B05D 3/10; C23C 14/34

(52) U.S. Cl. 427/551; 427/299; 204/192.12

(57) ABSTRACT

A method for making a nano-optical antenna array includes following steps. First, an insulative substrate is provided. Second, the insulative substrate is hydrophilicly treated. Third, a monolayer nanosphere array is formed on the insulative substrate. Fourth, a film is deposited on the monolayer nanosphere array. Fifth, the monolayer nanosphere array is removed.

### CROSS-REFERENCE TO RELATED APPLICATIONS

This application claims all benefits accruing under 35 U.S.C. §119 from China Patent Application No. 201010110157.1, filed on Feb. 6, 2010 in the China Intellectual Property Office, disclosure of which is incorporated herein by reference.

### BACKGROUND

1. Technical Field

The present disclosure relates to a method for making a nano-optical antenna array.

2. Description of Related Art

Nano-optical antenna arrays are widely used and studied. A method for making the nano-optical antenna array usually includes the step of lithography. However, the cost of the nano-optical antenna array is high because the lithography system, the photoresist, and the process of making the nano-optical antenna array are complicated.

What is needed, therefore, is to provide a low-cost and simple method for making a nano-optical antenna array.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a Scanning Electron Microscope (SEM) image of a hexagonally close-packed monolayer nanosphere array of one embodiment of a method for making a nano-optical antenna array.

FIG. 2 is a SEM of a nano-optical antenna array fabricated using the monolayer nanosphere array of FIG. 1.

FIG. 3 is a SEM of a squarely close-packed monolayer nanosphere array of one embodiment of a method for making a nano-optical antenna array.

FIG. 4 is a SEM image of a monolayer nanosphere array of FIG. 1 after tailoring.

FIG. 5 is a SEM of a nano-optical antenna array fabricated using the monolayer nanosphere array of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

References will now be made to the drawings to describe, in detail, various embodiments of the present method for making a nano-optical antenna array.

A method for making a nano-optical antenna array of one embodiment includes the following steps of:

step (a): providing an insulative substrate;

step (b): hydrophilicly treating the insulative substrate;

step (c): forming a monolayer nanosphere array on the insulative substrate;

step (d): depositing a film on the monolayer nanosphere array;

step (e): removing the monolayer nanosphere array.

In step (a), the insulative substrate can be made of a rigid or flexible material. The rigid material may be ceramic, glass, quartz, resin, silicon (Si), silicon dioxide (SiO₂), diamond, alumina, or gallium nitride (GaN). The flexible material may be poly ethylene terephthalate (PET), polycarbonate (PC), polyethylene (PE), or polyimide (PI). A size and a thickness of the insulative substrate can be determined according to need. The area of the insulative substrate can range from about 1 square centimeter to about 26 square centimeters. In one embodiment, the insulative substrate is a square glass plate with a side length of about 1 centimeter.

In step (b), when the insulative substrate is made of Si or SiO₂, the step (b) can include the following substeps of:

step (b1): cleaning the insulative substrate;

step (b2): soaking the insulative substrate in a hydrophilicly treating solution;

step (b3): rinsing and drying the insulative substrate.

In step (b1), the cleaning process can be a standard cleaning process used in room cleaning.

In step (b2), the hydrophilicly treating solution can be a mixture of NH₃, H₂O, H₂O₂, and H₂ O at a temperature in a range from about 30° C. to about 100° C. The soaking time is in a range from about 30 minutes to about 60 minutes. The hydrophilicly treating solution can be a mixture of NH₃·H₂O:H₂O₂:H₂O=0.5-1:1:5. In one embodiment, the hydrophilicly treating solution is NH₃·H₂O:H₂O₂:H₂O=0.6:1:5 with a temperature in a range from about 70° C. to about 80° C., and the soaking time is about 40 minutes.

In step (b3), the insulative substrate can be rinsed in deionized water for about 2 times to about 3 times. The insulative substrate can be dried by nitrogen gas blowing.

In step (b), if the insulative substrate is made of GaN, PET, or PE, the step (b) may include the following steps of:

step (b1a): cleaning the insulative substrate;

step (b2a): treating the insulative substrate in microwave plasma.

Step (b1a) is the same as the step (b1) described above. In step (b2a), the insulative substrate is put into a microwave plasma system and is treated by diffusing the microwave plasma on the surface of the insulative substrate. The microwave plasma system can be an oxygen plasma system to produce oxygen plasma, a chlorine plasma system to produce chlorine plasma, or an argon plasma system to produce argon plasma.

The power of the oxygen plasma system can be in a range from about 10 Watts to about 150 Watts. The input flow rate of the oxygen plasma can be about 10 standard cubic centimeters per minute. The working pressure of the oxygen plasma can be about 2 Pa. The treating time in the oxygen plasma can be in a range from about 1 second to about 30 seconds. In one embodiment, the insulative substrate is a polyethylene film, and the treating time in the oxygen plasma is in a range from about 5 seconds to about 10 seconds.

The power of the chlorine plasma system can be about 50 Watts. The input velocity of the chlorine plasma can be about 26 standard cubic centimeters per minute. The working pressure of the chlorine plasma can be in a range from about 2 Pa to about 10 Pa. The treating time in the chlorine plasma can be in a range from about 3 seconds to about 5 seconds.

The power of the argon plasma system can be about 50 Watts. The input velocity of the chlorine plasma can be about 4 standard cubic centimeters per minute. The working pressure of the chlorine plasma can be in a range from about 2 Pa to about 10 Pa. The treating time in the chlorine plasma can be in a range from about 10 seconds to about 30 seconds.

Step (c) can include the substeps of:

step (c1), preparing a nanosphere solution;

step (c2), forming a monolayer nanosphere solution on the insulative substrate;

step (c3), drying the monolayer nanosphere solution.

In step (c1), the diameter of the nanosphere can be in range from about 60 nanometers to about 500 nanometers, such as 100 nanometers, 200 nanometers, 300 nanometers, or 400 nanometers. The material of the nanosphere can be polymer or silicon. The polymer can be polymethyl methacrylate (PMMA) or polystyrene (PS). In one embodiment, a PS nanosphere solution can be synthesized by emulsion polymerization.

In step (c2), the monolayer nanosphere solution can be formed on the insulative substrate by dipping or spin-coating.

The method of dipping can include the substeps of:

step (c21): diluting the nanosphere solution;

step (c22): inserting the insulative substrate into the diluted nanosphere solution;

step (c23): drawing the insulative substrate out of the diluted nanosphere solution.

In step (c21), the nanosphere solution can be diluted by water or ethanol. In one embodiment, about 3 microlitres to about 5 microlitres PS nanosphere solution of about 0.01 wt. % to about 10 wt. % is mixed with 150 milliliters water, and about 1 microlitre to about 5 microlitres SDS of about 2 wt. % to obtain a mixture. The mixture can be kept for about 30 minutes to about 60 minutes. In addition, about 1 microlitre to about 3 microlitres SDS of about 4 wt. % can be added in the mixture to adjust the surface tension of the PS nanospheres.

In step (c22) and step (c23), the insulative substrate is inserted into and is drawn out of the diluted nanosphere solution slowly and obliquely. An angle between the surface of the insulative substrate and the level can be in a range from about 5 degrees to about 15 degrees. The speed of the inserting and drawing can be in a range from about 3 millimeters per hour to about 10 millimeters per hour. In one embodiment, the angle between the surface of the insulative substrate and the level is about 9 degrees, and the speed of the inserting and drawing is about 5 millimeters per hour.

The method of spin-coating includes the substeps of:

step (c21a): diluting the nanosphere solution;

step (c22a): dripping some diluted nanosphere solution on the surface of the insulative substrate;

step (c23a): spinning the insulative substrate at a speed from about 400 revolutions per minute to about 500 revolutions per minute for about 5 seconds to about 30 seconds;

step (c24a): increasing the spinning speed of the insulative substrate to a range from about 800 revolutions per minute to about 1000 revolutions per minute and maintaining it for about 30 seconds to about 2 minutes;

step (c25a): increasing the spinning speed of the insulative substrate to a range from about 1400 revolutions per minute to about 1500 revolutions per minute and maintaining it for about 10 seconds to about 20 seconds.

In step (c21a), the PS nanosphere solution of 10 wt. % can be diluted by mixing with a diluting agent at a volume ratio of about 1:1. The diluting agent can be a mixture of dodecylsodiumsulfate (SDS) and ethanol with a volume ratio of about 1:4000.

In step (c22a), the nanosphere solution of about 3 microlitres to about 4 microlitres is entirely dispersed onto the surface of the insulative substrate.

In steps (c23a) to step (c25a), a close-packed monolayer nanosphere solution was generated from the center to the edge of the insulative substrate.

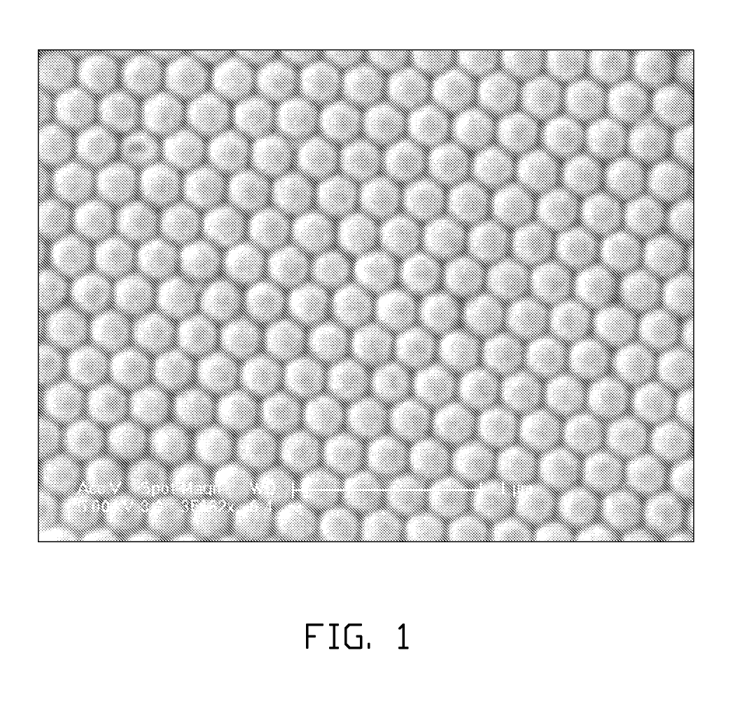

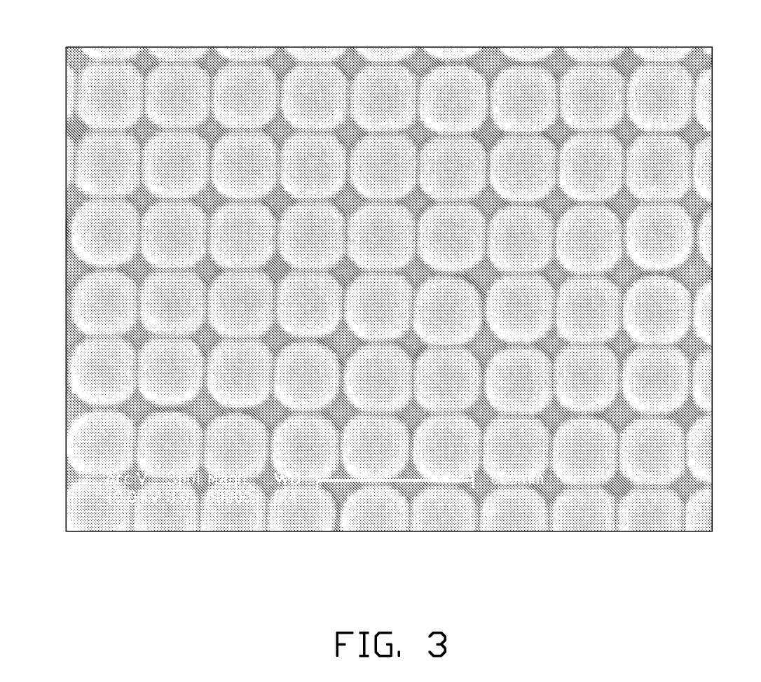

In step (c3), the monolayer nanospheres can be obtained. The monolayer nanospheres can be hexagonally close-packed, squarely close-packed, or concentrically close-packed. As shown in FIG. 1, in one embodiment, the monolayer nanospheres are hexagonally close-packed. As shown in FIG. 3, in one embodiment, the monolayer nanospheres are squarely close-packed.

An optional step (c4) of baking the monolayer nanospheres can be performed after the step (c3). The baking temperature can range from about 50° C. to about 100° C. and the baking time can range from about 1 minute to about 5 minutes.

In step (d), the film can be a metal film or a metal oxide film. In one embodiment, the metal film is deposited by electron beam evaporation or sputtering. The metal film is vertically deposited on the monolayer nanospheres and the surface of the insulative substrate between the adjacent nanospheres. The thickness of the metal film is in a range from about 20 nanometers to about 300 nanometers. The metal can be gold, silver, copper, aluminum, iron, cobalt, or nickel.

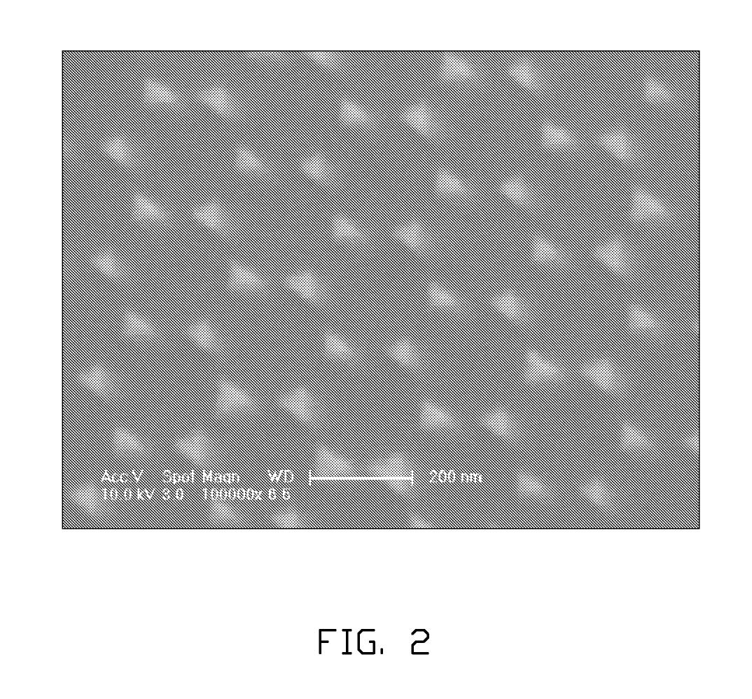

In step (e), the monolayer nanosphere array can be removed by dissolving in a stripping agent such as tetrahydrofuran (THF), acetone, butanone, cyclohexane, hexane, methanol, or ethanol. After the nanospheres are dissolved, the residual metal formed on a surface of the nanospheres before the monolayer nanosphere array are dissolved can be removed by rinsing. The remaining metal film forms a nano-optical antenna array on the surface of the insulative substrate. The monolayer nanosphere array and the metal film on a surface of the monolayer nanosphere array together can be removed by peeling with an adhesive tape. In one embodiment, because each three adjacent nanospheres are arranged in an equilateral triangle as shown in FIG. 1, a triangular pattern is formed in a space between the three adjacent nanospheres as shown in FIG. 2.

Furthermore, an optional step (f) of a secondary hydrophilicly treatment can be performed after step (b) and before step (c). In step (f), the insulative substrate is soaked in a SDS solution of about 1 wt. % to about 5 wt. % for about 2 hours to about 24 hours to obtain a hydrophilic surface. In one embodiment, the insulative substrate is soaked in a SDS solution of about 2 wt. % for about 10 hours. As shown in FIG. 3, squarely close-packed monolayer nanospheres can be obtained when the step (f) is performed. In the squarely close-packed monolayer nanospheres, the nanospheres in the same row or same column are arranged coaxially.

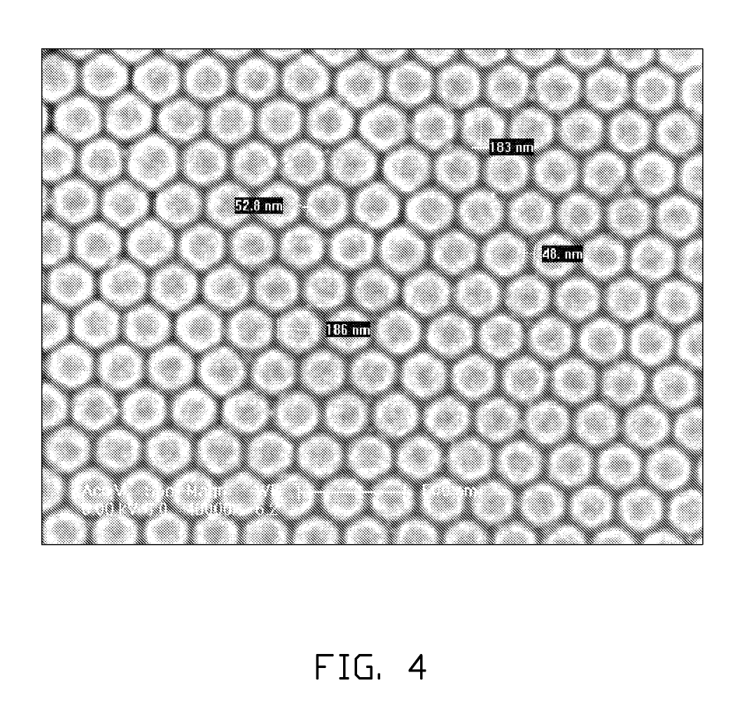

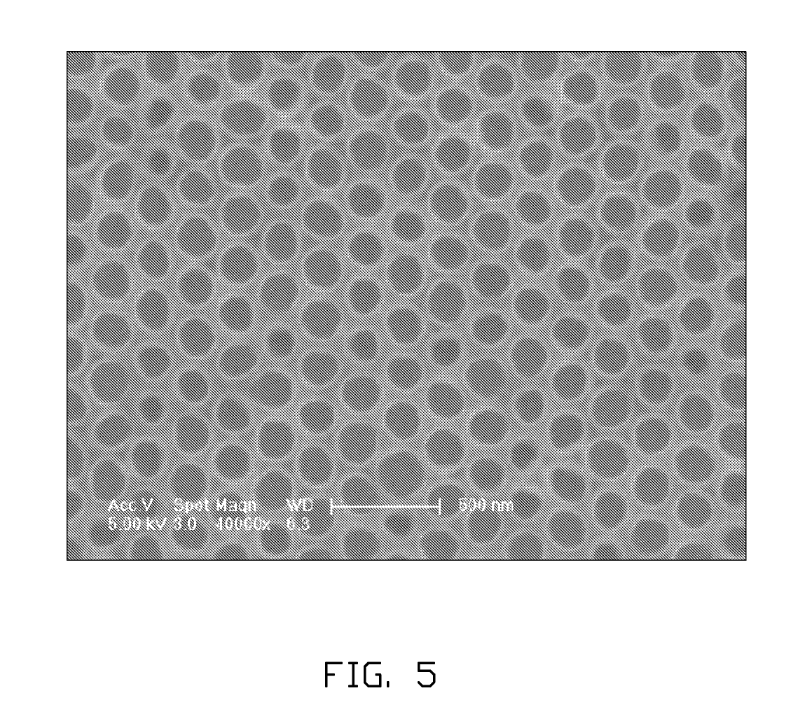

Furthermore, an optional step (g) of tailoring the monolayer nanospheres can be carried after the step (c) and before step (d). Step (g) can be carried out in a microwave plasma system. In one embodiment, the monolayer nanospheres are etched by oxygen plasma in an oxygen plasma system. The oxygen plasma diffuses to the surface of the monolayer nanospheres and etches the monolayer nanospheres. The nanospheres become smaller and gap between the adjacent nanospheres become greater as shown in FIG. 4. The power of the oxygen plasma system can be in a range from about 10 Watts. The input velocity of the oxygen plasma can be about 10 standard cubic centimeters per minute. The working pressure of the oxygen plasma can be about 2 Pa. The etching time in the oxygen plasma can be in a range from about 5 seconds to about 10 seconds. When the step (g) of tailoring is performed, the gaps between the adjacent nanospheres as shown in FIG. 1 become greater as shown in FIG. 4. The triangular pattern as shown in FIG. 2 becomes greater and adjacent triangular patterns connect with each other as shown in FIG. 5. Thus, a plurality of holes is defined by the remaining metal film. The plurality of holes can be used as a nano-optical antenna array.

It is to be understood that the above-described embodiments are intended to illustrate rather than limit the disclosure. Any elements described in accordance with any embodiments is understood that they can be used in addition or substituted in other embodiments. Embodiments can also be used together. Variations may be made to the embodiments without departing from the spirit of the disclosure. The above-described embodiments illustrate the scope of the disclosure but do not restrict the scope of the disclosure.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What is claimed is:

1. A method for making a nano-optical antenna array comprising steps of:
step (a), providing an insulative substrate;
step (b), hydrophilicly treating the insulative substrate;
step (c), forming a monolayer nanosphere array on the insulative substrate;
step (d), depositing a film on the monolayer nanosphere array; and
step (e), removing the monolayer nanosphere array.

2. The method of claim 1, wherein the insulative substrate is made of silicon or silicon dioxide, and step (b) comprises the following substeps of:
step (b1), cleaning the insulative substrate;
step (b2), soaking the insulative substrate in a hydrophilicly treating solution; and
step (b3), rinsing and drying the insulative substrate.

3. The method of claim 1, wherein the insulative substrate is made of gallium nitride, poly ethylene terephthalate, or polyethylene, and step (b) comprises the following substeps of:
step (b1′), cleaning the insulative substrate; and
step (b2′), treating the insulative substrate in a microwave plasma.

4. The method of claim 1, wherein step (c) comprises the substeps of:
step (c1), preparing a nanosphere solution;
step (c2), forming a monolayer nanosphere solution on the insulative substrate; and
step (c3), drying the monolayer nanosphere solution to obtain a monolayer nanosphere.

5. The method of claim 4, wherein step (c2) comprises the following substeps of:
step (c21): diluting the nanosphere solution;
step (c22): inserting the insulative substrate into the diluted nanosphere solution; and
step (c23): drawing the insulative substrate out of the diluted nanosphere solution.

6. The method of claim 5, wherein an angle between a surface of the insulative substrate and the level is in a range from about 5 degrees to about 15 degrees.

7. The method of claim 5, wherein a speed of the inserting and drawing is in a range from about 3 millimeters per hour to about 10 millimeters per hour in step (c22) and step (23).

8. The method of claim 4, wherein step (c2) comprises the following substeps of:
step (c21′): diluting the nanosphere solution to form a diluted nanosphere solution;
step (c22′): dripping the diluted nanosphere solution on a surface of the insulative substrate;
step (c23′): spinning the insulative substrate at a speed from about 400 revolutions per minute to about 500 revolutions per minute for about 5 seconds to about 30 seconds;
step (c24′): increasing a spinning speed of the insulative substrate to a range from about 800 revolutions per minute to about 1000 revolutions per minute for about 30 seconds to about 2 minutes;
step (c25′): increasing the spinning speed of the insulative substrate to a range from about 1400 revolutions per minute to about 1500 revolutions per minute for about 10 seconds to about 20 seconds.

9. The method of claim 4, wherein a step (c4) of baking the monolayer nanosphere can be performed after the step (c3).

10. The method of claim 1, wherein the monolayer nanosphere array is hexagonally close-packed, squarely close-packed, or concentrically close-packed.

11. The method of claim 1, wherein the film is a metal film or a metal oxide film.

12. The method of claim 1, wherein the film is deposited by a method of electron beam evaporation or sputtering.

13. The method of claim 1, wherein a thickness of the film is in a range from about 20 nanometers to about 300 nanometers.

14. The method of claim 1, wherein the monolayer nanosphere array is removed by dissolving in a stripping agent.

15. The method of claim 14, wherein the stripping agent is selected from the group consisting of tetrahydrofuran, acetone, butanone, cyclohexane, hexane, methanol, and ethanol.

16. The method of claim 1, wherein the monolayer nanosphere array and the film on a surface of the monolayer nanosphere array together are removed by peeling with an adhesive tape.

17. The method of claim 1, further comprising a step (f) of secondary hydrophilicly treating the insulative substrate after step (b) and before step (c).

18. The method of claim 17, wherein in step (f), the insulative substrate is soaked in a dodecylsodiumsulfate solution of about 1 wt % to about 5 wt % for about 2 hours to about 24 hours.

19. The method of claim 1, further comprising a step (g) of tailoring the monolayer nanosphere array after step (c) and before step (d).

20. A method for making a nano-optical antenna array comprising steps of:
step (a), providing an insulative substrate;
step (b), hydrophilicly treating the insulative substrate;
step (c), forming a monolayer nanosphere array on the insulative substrate;
step (d), depositing a metal in a gap of the monolayer nanosphere array; and
step (e), removing the monolayer nanosphere array.
